(19) United States
(12) Patent Application Publication
(10) Pub. No.: US 2026/0053052 A1
(43) Pub. Date: Feb. 19, 2026

(54) SEMICONDUCTOR PACKAGE

(71) Applicant: Samsung Electronics Co., Ltd., Suwon-si (KR)

(72) Inventors: Juil CHOI, Suwon-si (KR); Dongjun KIM, Suwon-si (KR); Hyunho KIM, Suwon-si (KR); Hyungjun PARK, Suwon-si (KR); Kwangok JEONG, Suwon-si (KR); Jaemok JUNG, Suwon-si (KR)

(73) Assignee: Samsung Electronics Co., Ltd., Suwon-si (KR)

(21) Appl. No.: 19/059,485

(22) Filed: Feb. 21, 2025

(30) Foreign Application Priority Data
Aug. 14, 2024 (KR) 10-2024-0108887

(51) Int. Cl. H01L 23/31; H01L 23/00; H01L 23/29; H01L 23/48; H01L 25/00; H01L 25/16; H10B 80/00

(52) U.S. Cl. CPC H01L 23/3135; H01L 23/481; H01L 24/16; H01L 24/32; H01L 24/73; H01L 25/16; H01L 25/50; H01L 23/293; H01L 2224/16148; H01L 2224/32014; H01L 2224/32145; H01L 2224/73204; H10B 80/00

(57) ABSTRACT

A semiconductor package includes a base chip including a semiconductor body and a through-electrode structure penetrating through the semiconductor body and having a protrusion portion protruding upwardly of the semiconductor body, an insulating pattern on a side surface and an upper surface of the base chip, a chip stack on the base chip and the insulating pattern, and an encapsulant on the insulating pattern and covering at least a portion of the chip stack. The insulating pattern includes a first insulating portion on a side surface of the semiconductor body, and a second insulating portion on an upper surface of the semiconductor body and covering a side surface of the protrusion portion of the through-electrode structure. The insulating pattern includes an inorganic insulating material, and the encapsulant includes an organic insulating material.

### CROSS-REFERENCE TO RELATED APPLICATION(S)

This application claims the benefit under 35 USC 119(a) of Korean Patent Application No. 10-2024-0108887 filed on Aug. 14, 2024 in the Korean Intellectual Property Office, the entire disclosure of which is incorporated herein by reference for all purposes.

### BACKGROUND

The present inventive concepts relate to semiconductor packages.

As electronic devices become lighter and more high-performance, the development of miniaturized and high-performance semiconductor packages is also desired in the semiconductor package field. To implement miniaturization, lightness, higher performance, and higher reliability of semiconductor packages, research and development of semiconductor packages in which multiple semiconductor chips are vertically stacked are continuously being conducted.

### SUMMARY

Example embodiments provide semiconductor packages having improved reliability.

According to an example embodiment, a semiconductor package includes a base chip including a semiconductor body and a through-electrode structure penetrating through the semiconductor body and having a protrusion portion protruding upwardly of the semiconductor body, an insulating pattern on a side surface and an upper surface of the base chip, a chip stack on the base chip and the insulating pattern, and an encapsulant on the insulating pattern and covering at least a portion of the chip stack. The insulating pattern includes a first insulating portion on a side surface of the semiconductor body, and a second insulating portion on an upper surface of the semiconductor body and covering a side surface of the protrusion portion of the through-electrode structure. The insulating pattern includes an inorganic insulating material, and the encapsulant includes an organic insulating material.

According to an example embodiment, a semiconductor package includes a base chip including a semiconductor body and a through-electrode structure penetrating through the semiconductor body and having a protrusion portion protruding upwardly of the semiconductor body, an insulating pattern on a side surface and an upper surface of the base chip, a chip stack on the base chip and the insulating pattern, and an encapsulant on the insulating pattern and surrounding at least a portion of the chip stack. The through-electrode structure includes a via plug, a barrier layer surrounding a side surface of the via plug, and an insulating spacer layer surrounding a side surface of the barrier layer. The insulating pattern and the encapsulant include different materials from each other.

According to an example embodiment, a semiconductor package includes a base chip, a chip stack on the base chip and including a plurality of first semiconductor chips stacked in a vertical direction, an insulating pattern including a first insulating portion and a second insulating portion, the first insulating portion being on a side surface of the base chip, the second insulating portion connected to the first insulating portion and extending between the base chip and the chip stack, and an encapsulant on the insulating pattern, the encapsulant covering at least a portion of a side surface of the chip stack and contacting the insulating pattern, the encapsulant including a material different from a material of the insulating pattern. The base chip is spaced from the encapsulant by the insulating pattern, a side surface of the insulating pattern and a side surface of the encapsulant are vertically aligned, and at least a portion of the first insulating portion has an upper surface at a level lower than an upper surface of the second insulating portion.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1A is a plan view illustrating a semiconductor package according to an example embodiment, and FIG. 1B is a cross-sectional view illustrating a cross-section taken along line I-I′ of FIG. 1A;

FIG. 2 is a cross-sectional view illustrating a semiconductor package according to an example embodiment;

FIG. 3 is a cross-sectional view illustrating a semiconductor package according to an example embodiment;

FIG. 4 is a cross-sectional view illustrating a semiconductor package according to an example embodiment; and

FIGS. 5A to 5H are cross-sectional views schematically illustrating a process of manufacturing a semiconductor package according to an example embodiment.

### DETAILED DESCRIPTION

Hereinafter, some example embodiments will be described with reference to the attached drawings. Unless otherwise specifically stated, in this specification, terms such as ‘upper portion’, ‘upper surface’, ‘lower portion’, ‘lower surface’, ‘side’, ‘side surface’, and the like are based on the drawings, and may actually vary depending on the direction in which components are disposed.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

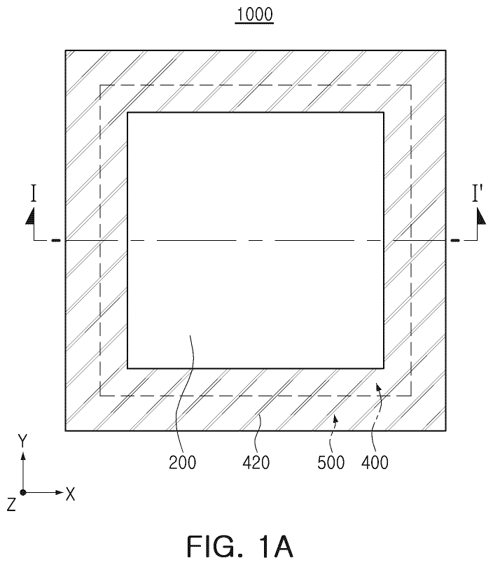

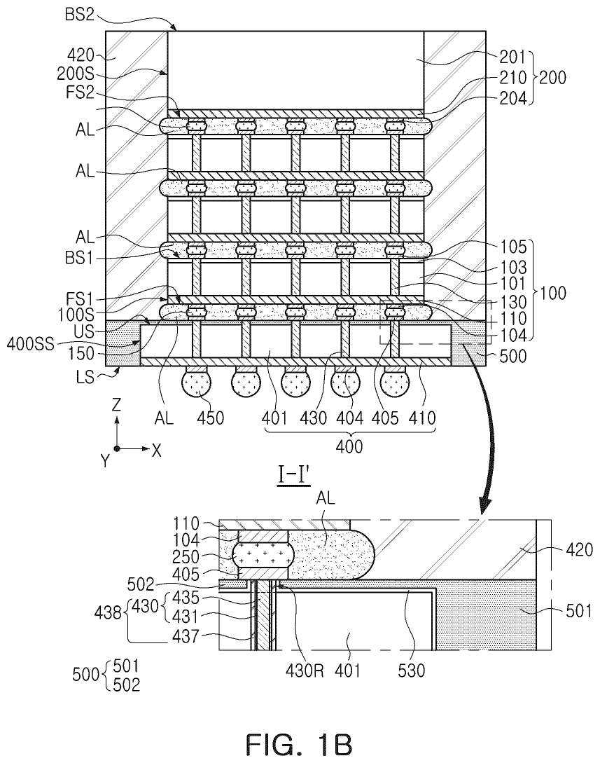

FIG. 1A is a plan view illustrating a semiconductor package according to an example embodiment, and FIG. 1B is a cross-sectional view illustrating a cross-section taken along line I-I′ of FIG. 1A.

Referring to FIGS. 1A and 1B, a semiconductor package 1000 according to an example embodiment may include a base chip 400, a plurality of first semiconductor chips 100 on the base chip 400, a second semiconductor chip 200, bump structures 150, adhesive layers (AL), an encapsulant 420, and an insulating pattern 500.

The base chip 400 may include a semiconductor body 401, a device layer 410, and a through-electrode structure 438. The base chip 400 may be, for example, a buffer chip including a plurality of logic elements and/or memory elements in the device layer 410. Accordingly, the base chip 400 may transmit signals from a chip stack of the plurality of first semiconductor chips 100 and the second semiconductor chip 200 stacked thereon (hereinafter, interchangeably referred to as “chip stack 100 and 200”), to the outside thereof, and may also transmit signals and power from the outside to the chip stack 100 and 200. The base chip 400 may perform both logic and memory functions through logic elements and memory elements, but according to an example embodiment, the base chip 400 may perform only logic functions by including only logic elements.

The semiconductor body 401 may include, for example, a semiconductor element such as silicon or germanium (Ge), or a compound semiconductor such as silicon carbide (SiC), gallium arsenide (GaAs), indium arsenide (InAs), or indium phosphide (InP). The semiconductor body 401 may have a silicon on insulator (SOI) structure. The semiconductor body 401 may include a conductive region, for example, a well doped with impurities, or a structure doped with impurities.

The device layer 410 is disposed on the lower surface of the semiconductor body 401 and may include various types of elements. For example, the device layer 410 may include various active devices and/or passive devices such as system Large Scale Integration (LSI), CMOS Imaging Sensors (CISs), and Micro-Electro-Mechanical Systems (MEMS), FETs such as planar Field Effect Transistors (FET) or FinFETs, memory devices such as flash memories, Dynamic Random Access Memories (DRAMs), Static Random Access Memories (SRAMs), Electrically Erasable Programmable Read-Only Memories (EEPROMs), Phase-change Random Access Memories (PRAMs), Magnetoresistive Random Access Memories (MRAMs), Ferroelectric Random Access Memories (FeRAMs), Resistive Random Access Memories (RRAMs), and/or logic devices such as ANDs, ORs, and NOTs.

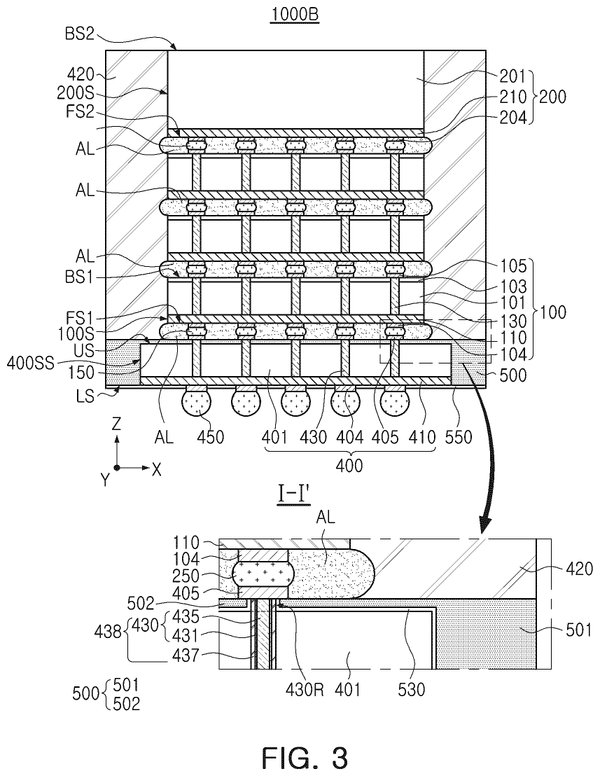

The device layer 410 may include an interlayer insulating layer (not illustrated) and a multilayer wiring layer (not illustrated) on the devices described above. The interlayer insulating layer (not illustrated) may include silicon oxide or silicon nitride. The multilayer wiring layer (not illustrated) may include multilayer wiring and/or vertical contacts. The multilayer wiring layer (not illustrated) may connect the elements of the device layer 410 to each other, connect the elements to the conductive region of the semiconductor body 401, or connect the elements to the lower pad 404. According to an example embodiment, a lower protective layer (see ‘550’ of FIG. 3 may be further formed on the lower surface of the device layer 410.

The through-electrode structure 438 may include a through-electrode 430 that penetrates the semiconductor body 401 in a vertical direction (e.g., in the Z-axis direction) and provides an electrical path connecting the upper pad 405 and the lower pads 404, and an insulating spacer layer 437 surrounding the side surface of the through-electrode 430.

Each of the through-electrodes 430 may include a via plug 435 and a barrier layer 431 surrounding a side surface of the via plug 435. The via plug 435 may include a metal material, for example, tungsten (W), titanium (Ti), aluminum (Al), or copper (Cu). The via plug 435 may be formed by a plating process, a PVD process, or a CVD process. The barrier layer 431 may include titanium (Ti), titanium nitride (TiN), tantalum (Ta), or tantalum nitride (TaN), and may be formed by a plating process, a PVD process, or a CVD process. Upper pads 405 may be disposed on respective upper surfaces of the through-electrodes 430, and in detail, respective upper surfaces of the via plug 435 and the barrier layer 431 may be in direct contact with the lower surfaces of the upper pads 405. The through-electrode 430 may have a protrusion portion 430R protruding from the upper surface 401US of the semiconductor body 401. The through-electrodes 430 may be electrically connected to the chip stack 100 and 200.

The insulating spacer layer 437 including an insulating material (for example, High Aspect Ratio Process (HARP) oxide) such as silicon oxide, silicon nitride, or silicon oxynitride may be formed between the side surface of the through-electrodes 430 and the semiconductor body 401. The insulating spacer layer 437 may penetrate at least a portion of the semiconductor body 401, may extend in a vertical direction (e.g., in the Z-axis direction), and may surround the side surface of the through-electrode 430. The insulating spacer layer 437 may be exposed from the upper surface 401US of the semiconductor body 401 to surround the protrusion portion 430R protruding from the upper surface 401US of the semiconductor body 401. The side surface of the exposed insulating spacer layer 437 may be surrounded by the second insulating portion 502 of the insulating pattern 500.

The buffer insulating layer 530 may cover at least a portion of each of the side surface 400SS and the upper surface US of the base chip 400 (e.g., the upper surface 401US of the semiconductor body 401). The buffer insulating layer 530 may conformally extend along the side surface 400SS and the upper surface US of the base chip 400 and may surround a side surface of a protrusion portion 430R of a through-electrode structure 438 protruding from the upper surface 401US of a semiconductor body 401. In detail, the buffer insulating layer 530 may conformally extend from a portion disposed between a first insulating portion 501 of the insulating pattern 500 and the semiconductor body 401 to between a side surface of the protrusion portion 430R of the through-electrode structure 438 and a second insulating portion 502 of the insulating pattern 500. The buffer insulating layer 530 may conformally cover a side surface of the insulating spacer layer 431. The second portion 502 of the insulating pattern 500 may be disposed on at least a portion of the buffer insulating layer 530. The buffer insulating layer 530 may include an insulating material such as silicon oxide.

The upper pad 405 may be disposed on the base chip 400 and may be disposed on the through-electrode structure 438. In detail, the lower surface of the upper pad 405 may be in direct contact with the upper surface of the through-electrode structure 438 and the upper surface of the second insulating portion 502 of the insulating pattern 500. The upper pad 405 may include, for example, at least one of aluminum (Al), copper (Cu), nickel (Ni), tungsten (W), platinum (Pt), or gold (Au). The lower pad 404 may be disposed on the lower surface LS of the base chip 400 (or the lower surface of the device layer 410 and may include a material similar to that of the upper pad 405. However, the materials of the upper pad 405 and the materials of the lower pad 404 are not limited to the above materials. The upper pad 405 and the lower pad 404 may be electrically connected through the via plug 435 of the via through-electrode 430.

External connection conductors 450 may be disposed below the base chip 400. The external connection conductors 450 may be connected to the lower pads 404 on the lower surface of the base chip 400, respectively, and may be electrically connected to the plurality of first semiconductor chips 100 and the second semiconductor chip 200 through the through-electrode 430. The external connection conductors 450 may include, for example, tin (Sn) or an alloy (e.g., Sn—Ag—Cu) containing tin (Sn). According to an example embodiment, the external connection conductors 450 may have a form in which a metal pillar and a solder ball are combined. The external connection conductors 450 may be electrically connected to an external device such as a module substrate, a system board, or the like. The base chip 400 may have a width greater than the width of each of the plurality of first semiconductor chips 100 and the second semiconductor chip 200 in the horizontal direction US (e.g., X and/or Y direction that is parallel to the upper surface US of the base chip 400).

The chip stack 100 and 200 may include a plurality of first semiconductor chips 100 and the second semiconductor chip 200, sequentially stacked on the base chip 400. In FIG. 1B, three first semiconductor chips 100 are illustrated as being stacked, but the number is not limited thereto.

A plurality of first semiconductor chips 100 may be disposed on a base chip 400 and may include a first substrate 101, a first back protection layer 103, first front pads 104 disposed on a first front surface FS1, first back pads 105 disposed on a first back surface BS1, a first element layer 110, and first through vias 130 electrically connecting the first front pads 104 and the first back pads 105. The first substrate 101, the first back protection layer 103, the first front pads 105, the first back pads 104, the first element layer 110, and the first through-vias 130 have the same or similar characteristics as the corresponding elements (e.g., the semiconductor body 401, the upper protective layer 403, the upper pad 405, the lower pad 404, the device layer 410, and the through-electrodes 430) of the base chip 400 described above, Thus, a duplicate description is omitted. The first semiconductor chip 100 may have a first front surface FS1 on which first front pads 104 are disposed, a first back surface BS1 on which first back pads 105 are disposed, and a first side surface 100S extending from an edge of the first front surface FS1 to an edge of the first back surface BS1.

The plurality of first semiconductor chips 100 may each have a first front surface FS1 on which first front pads 104 are disposed, a first back surface BS1 on which first back pads 105 are disposed, and a first side surface 100S extending from an edge of the first front surface FS1 to an edge of the first back surface BS1. The plurality of first semiconductor chips 100 may be electrically connected to each other through first through vias 130 that electrically connect the first front pads 104 and the first back pads 105. According to an example embodiment, the number of the plurality of first semiconductor chips 100 may be 1, 2, or 4 or more.

The second semiconductor chip 200 may be placed on the first semiconductor chip 100 and may include a second substrate 201, second front pads 204 placed on a second front surface FS2 of the second substrate 201, and a second element layer 210. The second substrate 201, the second front pads 204, and the second element layer 210 have the same or similar characteristics as the corresponding elements (e.g., the semiconductor body 401, the lower pad 404, and the device layer 410) of the base chip 400, described above. Thus, a duplicate description is omitted. The second semiconductor chip 200 may have the second front surface FS2 on which second front pads 204 are disposed, a second back surface BS2 opposite to the second front surface, and a second side 200S extending from an edge of the second front surface FS2 to an edge of the second back surface BS2. The second semiconductor chip 200 may be the uppermost semiconductor chip of the chip stack 100 and 200, and the second back surface BS2 may be exposed from the encapsulant 420. In addition, the second semiconductor chip 200 may have a thickness greater than a thickness of each of the plurality of first semiconductor chips 100.

The chip stack 100 and 200 may be composed of memory chips or memory elements that store or output data based on address commands and control commands received from the base chip 400. For example, the chip stack 100 and 200 may include volatile memory elements such as DRAM and SRAM, or nonvolatile memory elements such as PRAM, MRAM, FeRAM, or RRAM. The uppermost semiconductor chip 200 (hereinafter, “second semiconductor chip”) among the chip stack 100 and 200 does not include a through via, and the back surface BS2 thereof may be exposed from the encapsulant 420, but is not limited thereto.

The insulating pattern 500 may include a first insulating portion 501 surrounding the side surface of the base chip 400, and a second insulating portion 502 disposed between the upper surface 401US of the semiconductor body 401 and the lower surfaces of the upper pads 405, and surrounding the side surfaces of respective protrusion portions of the through-electrodes 430. In detail, the first insulating portion 501 may be disposed at the same level as the base chip 400 among the insulating patterns 500 and may correspond to a portion that overlaps the base chip 400 in a horizontal direction (e.g., in the X-axis direction or the Y-axis direction), and the second insulating portion 502 may be disposed on the upper surface US of the base chip 400 and may correspond to a portion that overlaps the base chip 400 in a vertical direction (e.g., in the Z-axis direction). The first insulating portion 501 and the second insulating portion 502 may be integrally connected or may be an integral body.

At least a portion of the first insulating portion 501 may be located at the same level as the base chip 400. On a plane, the first insulating portion 501 may have a structure surrounding the base chip 400. At least a portion of the first insulating portion 501 may not overlap the base chip 400 in a horizontal direction and may be located at a level higher than the top of the base chip 400, but is not limited thereto. The upper surface of the first insulating portion 501 may be in direct contact with the lower surface of the encapsulant 420.

The second insulating portion 502 may be disposed between the upper surface 401US of the semiconductor body 401 and the lower surface of the upper pads 405. The second insulating portion 502 covers the upper surface 401US of the semiconductor body 401, and may surround a side surface of a protrusion portion 430R of the through-electrodes 430 protruding from the upper surface 401US of the semiconductor body 401, and may extend in a horizontal direction (e.g., in the X-axis direction or the Y-axis direction) parallel to the upper surface 401US of the semiconductor body 401. In detail, the second insulating portion 502 may surround a side surface of the insulating spacer layer 437. The upper surface of the second insulating portion 502 may be coplanar with respective upper surfaces of the insulating spacer layers 437 and may be coplanar with respective upper surfaces of the through-electrodes 430. The second insulating portion 502 may vertically separate the upper pads 405 and the semiconductor body 401 of the base chip 400 in the Z-axis direction. The second insulating portion 502 is disposed on the upper surface US of the base chip 400 and may serve as a protective insulating layer.

The insulating pattern 500 may include an insulating material. For example, the insulating pattern 500 may include an inorganic insulating material such as silicon nitride (SiN). The first insulating portion 501 and the second insulating portion 502 may include the same material.

When a sealing layer formed of or including an organic insulating material surrounds the base chip 400, a volume deformation of the sealing layer may occur due to higher heat applied during the manufacturing process of the semiconductor package. Such heat may cause movement of the base chip 400 within the semiconductor package, thereby resulting in reduced reliability of the semiconductor package. At least some example embodiments of the present inventive concepts may improve the reliability problem of a semiconductor package due to thermal deformation by introducing an insulating pattern 500 formed of or including a material (e.g., an inorganic insulating material such as SiN) that is different from an organic insulating material included in an encapsulant 420 to be located at the same level as at least a portion of a base chip 400 and to have a structure covering a side surface 400SS of the base chip 400.

Bump structures 150 may be disposed between the base chip 400 and the first semiconductor chip 100 at the lowest level and between the respective chip stack 100 and 200. For example, the bump structures 150 may include bump structures 150 disposed between the base chip 400 and the first front surface FS1 of the lowermost first semiconductor chip 100, and bump structures 150 disposed between the second front surface FS2 of the second semiconductor chip 200 and the uppermost first semiconductor chip 100. The bump structures 150 may electrically connect pads facing each other. The bump structures 150 may include, for example, tin (Sn), indium (In), bismuth (Bi), antimony (Sb), copper (Cu), silver (Ag), zinc (Zn), lead (Pb), and/or alloys thereof. The above alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like.

The adhesive layers (AL) may surround the bump structures 150, between the base chip 400 and the lowermost first semiconductor chip 100, and between an adjacent chips from among the chip stack 100 and 200. In addition, the adhesive layers (AL) may surround the first front pads 104 and the upper pads 405 between the base chip 400 and the lowermost first semiconductor chip 100, surround the first front pads 104 and the first back pads 105 between the plurality of first semiconductor chips 100, and surround the first back pads 105 and the second front pads 204 between the uppermost first semiconductor chip 100 and the second semiconductor chip 200. The adhesive layers (AL) may fix the vertically adjacent semiconductor chips in the stacked chip stack 100 and 200. The adhesive layers (AL) may have a fillet protruding outwardly from respective side surfaces 100S and 200S of the semiconductor chips included in the chip stack 100 and 200, but are not limited thereto, and respective side surfaces of the adhesive layers (AL) may be coplanar with respective side surfaces 100S and 200S of the semiconductor chips included in the chip stack 100 and 200. The adhesive layers (AL) may be a Non Conductive Film (NCF) or a Molded Underfill (MUF), but are not limited thereto. The adhesive layers (AL) may include at least one of an epoxy resin, silica (SiO₂), an acrylic copolymer, or combinations thereof.

The encapsulant 420 may seal the chip stack 100 and 200 on the base chip 400 and the insulating pattern 500. The side surface of the encapsulant 420 may be aligned vertically with the side surface of the first insulating pattern 501 among the insulating patterns 500. The encapsulant 420 may expose the back surface BS2 of the second semiconductor chip 200 disposed at the uppermost side among the chip stack 100 and 200. According to an example embodiment, the encapsulant 420 may cover the back surface BS2 of the second semiconductor chip 200. The encapsulant 420 may be formed of or include an insulating material, and may be formed of or include an organic insulating material such as an Epoxy Mold Compound (EMC), for example, but the material of the encapsulant 420 is not particularly limited. The encapsulant 420 may surround the side surface of the chip stack 100 and 200. The encapsulant 420 may be in direct contact with the respective side surfaces 100S and 200S of the semiconductor chips included in the chip stacks 100 and 200 and the side surfaces of the adhesive layers (AL), and the encapsulant 420 may cover the upper surface of the insulating pattern 500. The encapsulant 420 may be spaced apart from the base chip 400 by the insulating pattern 500. According to an example embodiment, a heat dissipation structure (not illustrated) may be disposed on the upper portion of the encapsulant 420. The heat dissipation structure (not illustrated) may control warpage of the semiconductor package 1000 and release heat generated in the chip stacks 100 and 200 to the outside.

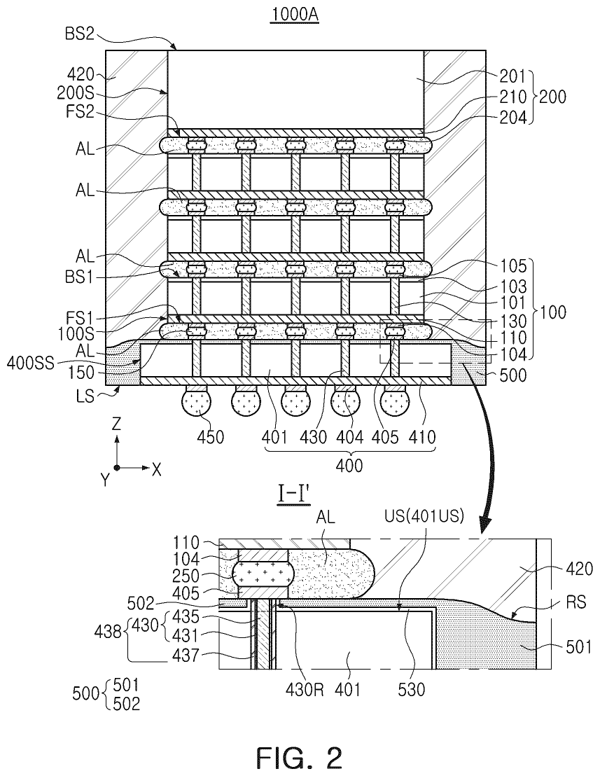

FIG. 2 is a cross-sectional view illustrating a semiconductor package 1000A according to an example embodiment.

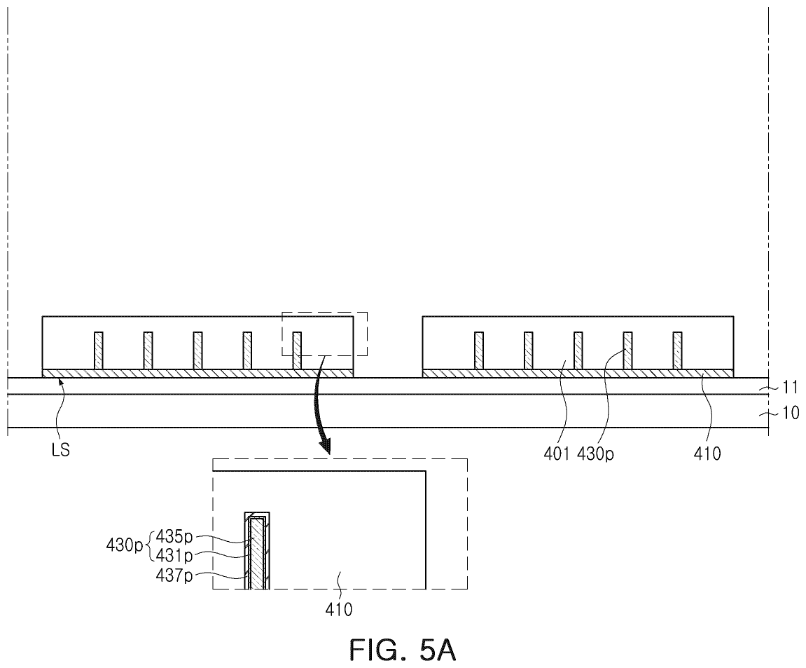

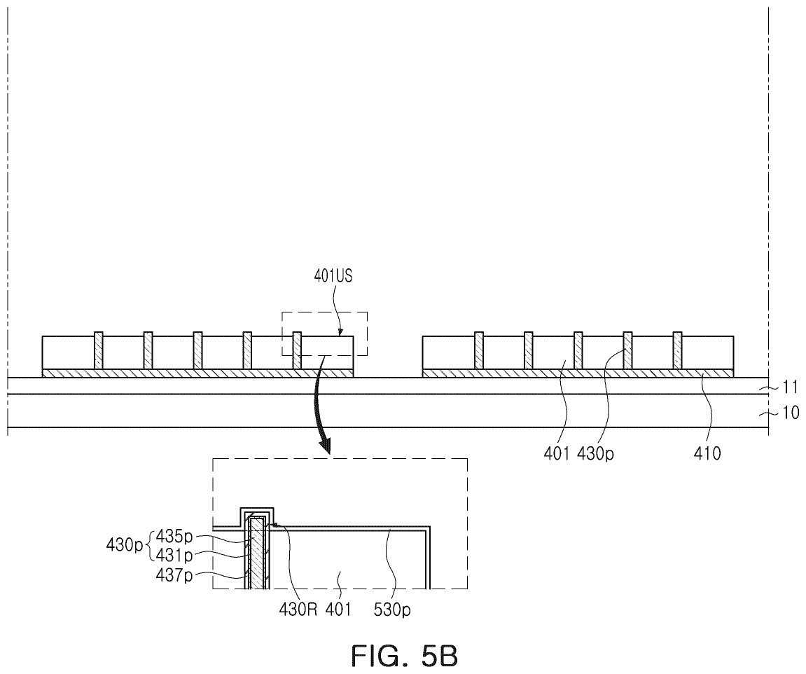

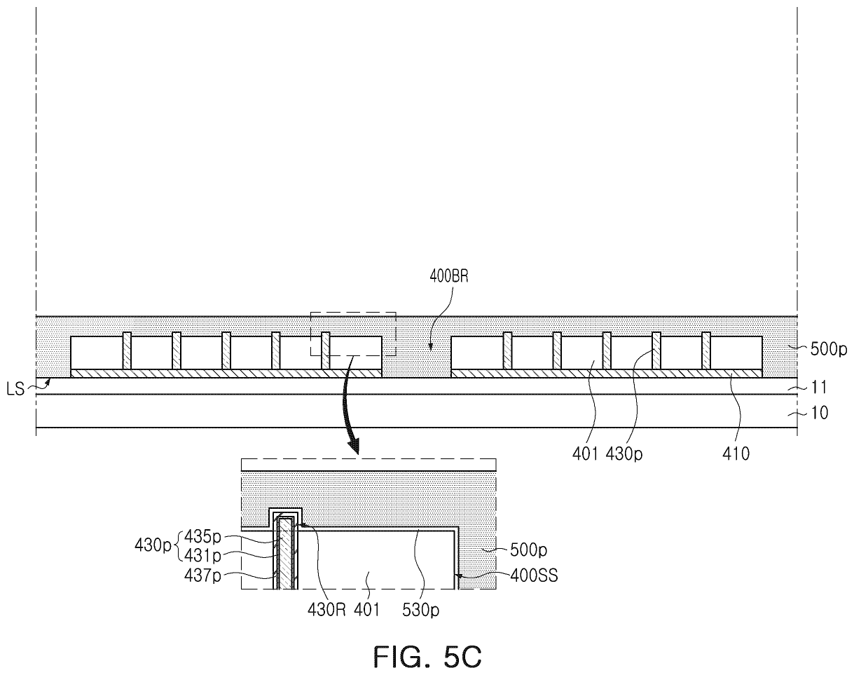

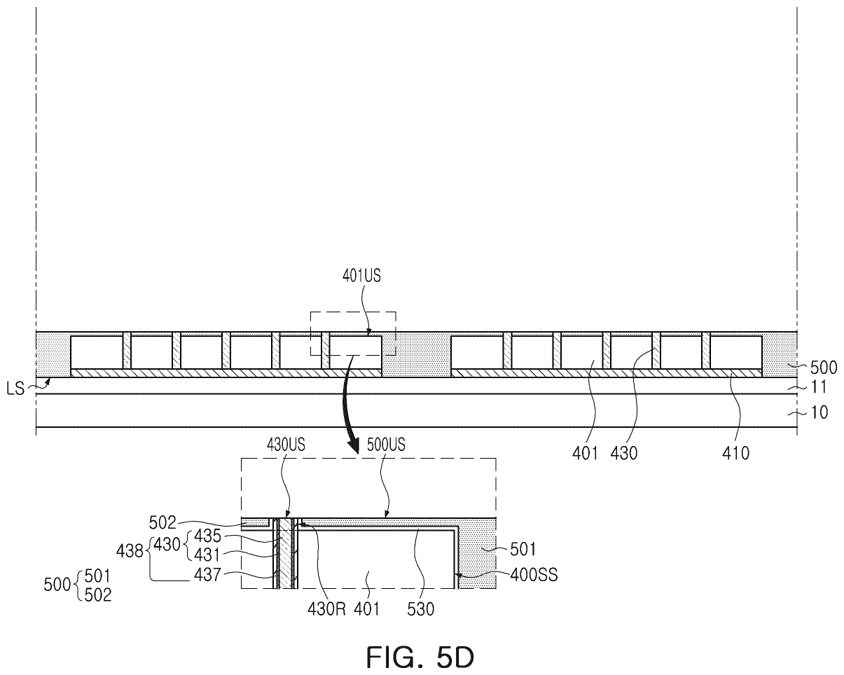

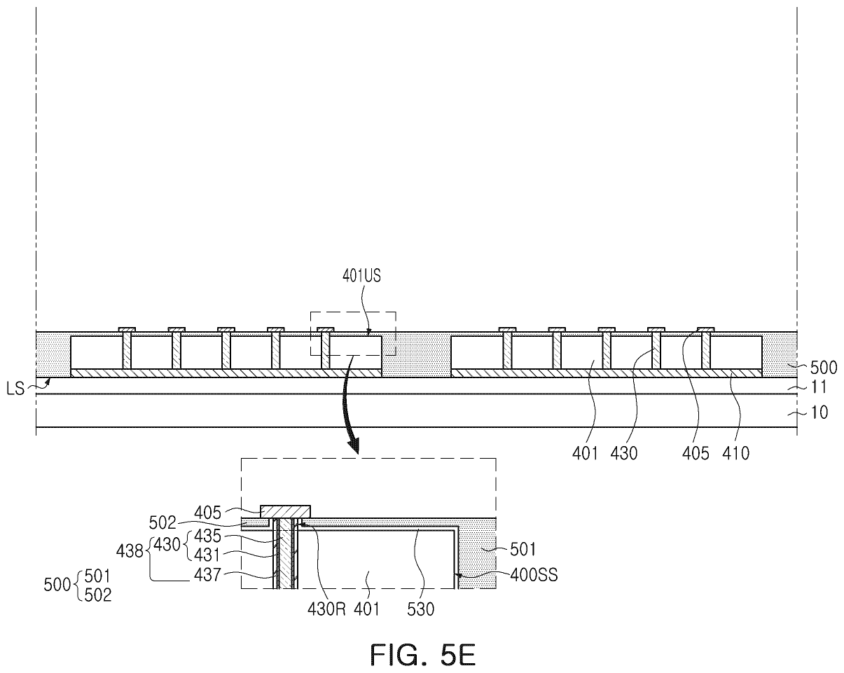

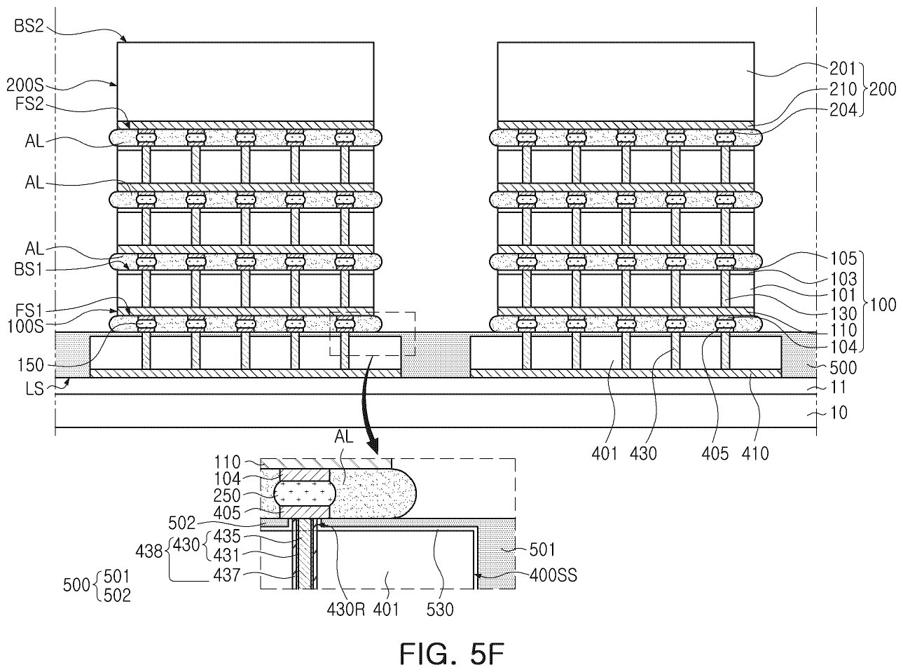

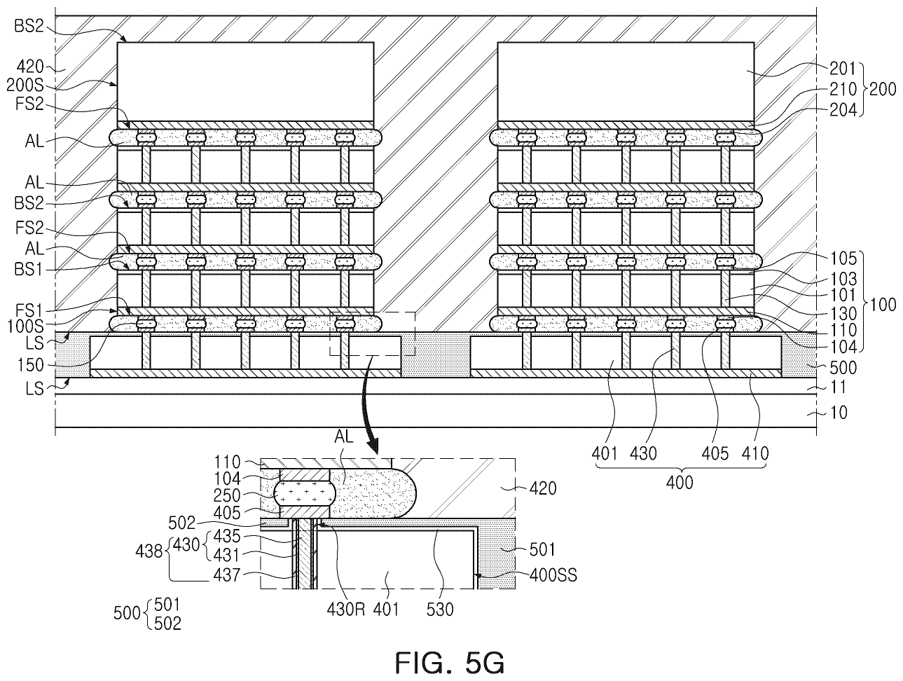

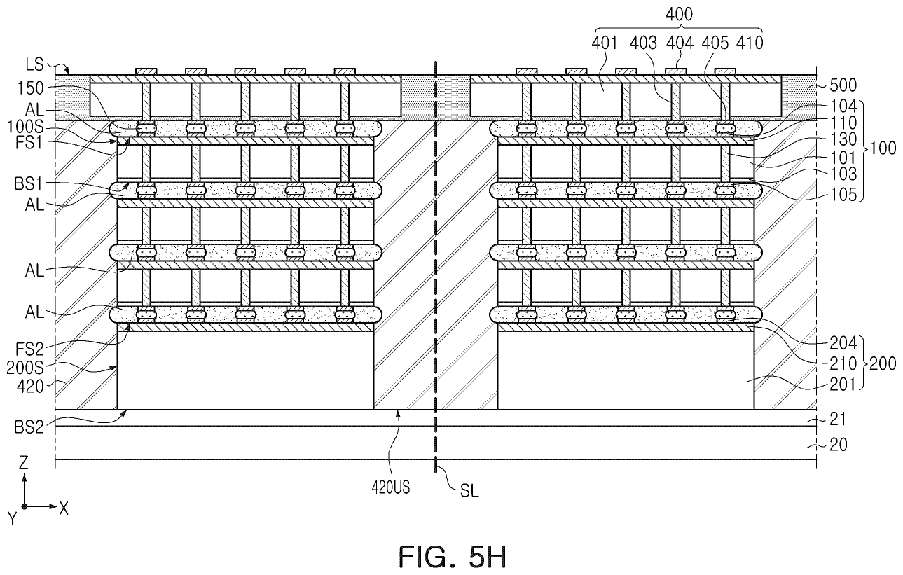

Referring to FIG. 2, the semiconductor package 1000A of an example embodiment may have the same or similar features as those described with reference to FIGS. 1A and 1B, except that a portion of the recess RS exists on the upper portion of the first insulating portion 501 of the insulating pattern 500. In the present example embodiment, the upper region of the first insulating portion 501 may have a form in which at least a portion is removed through a process such as CMP (Chemical Mechanical Polishing) (see FIG. 5D below). In the present example embodiment, the first insulating portion 501 may have a form in which at least a portion of the preliminary insulating pattern 500p (see FIG. 5C) is removed more in an area that does not vertically overlap with the base chip 400 in the forming process of the insulating pattern 500. At least a portion of the upper surface of the first insulating portion 501 may have a concave recess (RS) toward the lower surface of the first insulating portion 501. When viewed from the upper surface 401US of the semiconductor body 401, at least a portion of the upper surface of the first insulating portion 501 may be located at a lower level than the upper surface of the second insulating portion 502. The level of the upper surface of the insulating pattern 500 may become lower as moving from the second insulating portion 502 to the first insulating portion 501 or as moving away from the side surface 400SS of the base chip 400. In an example embodiment, the level of the upper surface of the first insulating portion 501 may be lower than the level of the upper surface US of the base chip 400, but is not limited thereto. The encapsulant 420 may be disposed on the insulating pattern 500 and may be in contact with at least portions of respective upper surfaces of the first insulating portion 501 and the second insulating portion 502. The encapsulant 420 may have a first lower end in a region that vertically overlaps the semiconductor body 401, and a second lower end that is disposed at a lower level than the first lower end in a region that does not vertically overlap the semiconductor body 401.

FIG. 3 is a cross-sectional view illustrating a semiconductor package 1000B according to an example embodiment.

Referring to FIG. 3, the semiconductor package 1000B of an example embodiment may have the same or similar features as those described with reference to FIG. 1A and FIG. 2, except that it further includes a lower protective layer 550 disposed on the lower surface of the base chip 400. The lower protective layer 550 is formed on respective lower surfaces of the base chip 400 and the insulating pattern 500, and may protect the device layer 410. The lower protective layer 550 may surround at least a portion of the side surface of the lower pad 404 disposed on the lower surface of the base chip 400. The lower protective layer 550 may include the same material as the insulating pattern 500, but is not limited thereto. The lower protective layer 550 may be formed of or include an insulating layer such as silicon oxide, silicon nitride, or silicon oxynitride, but the material of the lower protective layer 550 is not limited to the above materials. For example, the lower protective layer 550 may be formed of or include a polymer such as Polyimide (PI) or Photosensitive polyimide (PSPI). In the semiconductor package 1000B of the present example embodiment, the lower protective layer 550 is positioned below the device layer 410 of the base chip 400, thereby physically and electrically protecting the device layer 410, and by covering the area around the interface between the base chip 400 and the insulating pattern 500 (or the side surface 400SS of the base chip 400), where cracks may occur due to the difference in thermal expansion coefficient between the base chip 400 and the insulating pattern 500, reliability of the semiconductor package may be further improved.

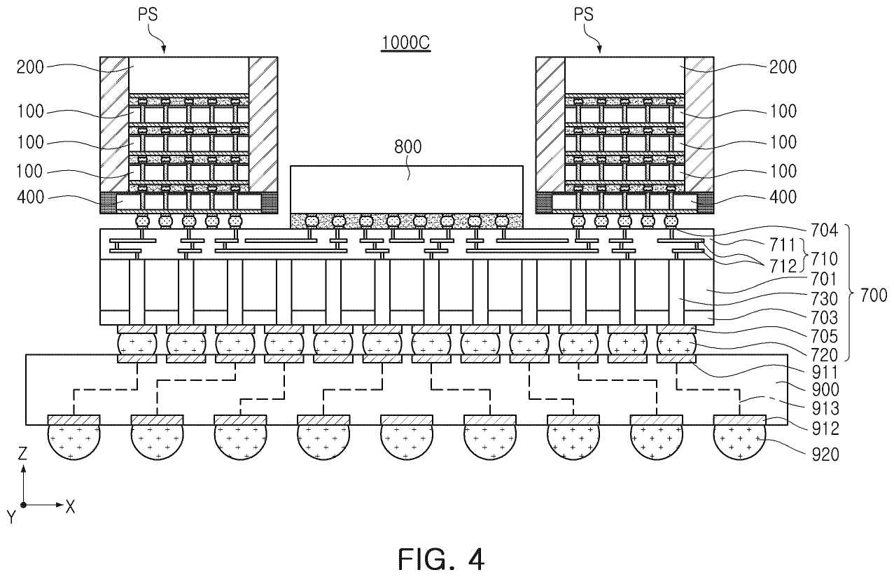

FIG. 4 is a cross-sectional view illustrating a semiconductor package 1000C according to an example embodiment.

Referring to FIG. 4, the semiconductor package 1000C of an example embodiment may include a package substrate 900, an interposer substrate 700, at least one chip structure PS, and a processor chip 800. The chip structure PS may have the same or similar characteristics as the semiconductor packages 1000, 1000A and 1000B described with reference to FIGS. 1A to 3.

The package substrate 900 is a support substrate on which the interposer substrate 700, the processor chip 800, and the chip structure PS are mounted, and may be a semiconductor package substrate including a printed circuit board (PCB), a ceramic substrate, a glass substrate, a tape wiring substrate, or the like. The body of the package substrate 900 may include different materials depending on the type of the substrate. For example, when the package substrate 900 is a printed circuit board, the package substrate 900 may be in the form of a body copper-clad laminate or a copper-clad laminate with a wiring layer additionally laminated on one side or both sides.

The package substrate 900 may include a lower terminal 912, an upper terminal 911, and a rewiring circuit 913. The upper terminal 911, the lower terminal 912, and the redistribution circuit 913 may form an electrical path connecting the lower surface and the upper surface of the package substrate 900. The upper terminal 911, the lower terminal 912, and the redistribution circuit 913 may include a metal material, for example, at least one metal from among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or carbon (C), or an alloy including two or more of those metals. An external connection terminal 920 connected to the lower terminal 912 may be disposed on the lower surface of the package substrate 900. The external connection terminal 920 may include tin (Sn), indium (In), bismuth (Bi), antimony (Sb), copper (Cu), silver (Ag), zinc (Zn), lead (Pb), and/or alloys thereof.

The interposer substrate 700 may include a substrate 701, a lower protective layer 703, a lower pad 705, an interconnect structure 710, a metal bump 720, and a through via 730. The chip structure PS and the processor chip 800 may be electrically connected to each other via the interposer substrate 700.

The substrate 701 may be formed of or include, for example, any one of a silicon, organic, plastic, or glass substrate. When the substrate 701 is a silicon substrate, the interposer substrate 700 may be referred to as a silicon interposer. Unlike what is illustrated in the drawing, if the substrate 701 is an organic substrate, the interposer substrate 700 may be referred to as a panel interposer.

A lower protective layer 703 may be disposed on the lower surface of the substrate 701, and a lower pad 705 may be disposed under the lower protective layer 703. The lower pad 705 may be connected to a through via 730. The chip structure PS and the processor chip 800 may be electrically connected to the package substrate 600 through metal bumps 720 disposed under the lower pad 705.

The interconnection structure 710 may be disposed on the upper surface of the substrate 701 and may include an interlayer insulating layer 711 and a single-layer or multilayer wiring structure 712. If the interconnection structure 710 is formed of or includes a multilayer wiring structure, wiring patterns of different layers may be connected to each other through contact vias.

The through via 730 may penetrate the substrate 701 to extend from the upper surface of the substrate 701 to the lower surface of the substrate 701. In addition, the through via 730 may extend into the interior of the interconnection structure 710 and be electrically connected to the wirings of the interconnection structure 710. When the substrate 701 is silicon, the through via 730 may be referred to as a TSV. Depending on an example embodiment, the interposer substrate 700 may include only the interconnection structure therein and may not include the through via.

The interposer substrate 700 may be used for converting or transmitting an input electrical signal between the package substrate 900 and the chip structure (PS) and/or the processor chip 800. Therefore, the interposer substrate 700 may not include components such as active components or passive components. Depending on an example embodiment, the interconnection structure 710 may be disposed below the through via 730. For example, the positional relationship between the interconnect structure 710 and the through via 730 may be relative.

The metal bump 720 may electrically connect the interposer substrate 700 and the package substrate 900. The chip structure PS may be electrically connected to the metal bump 720 through the interconnection structure 710 and the through via 730. According to an example embodiment, the lower pads 705 used for power or ground may be integrated and connected together to the metal bump 720, so that the number of lower pads 705 may be greater than the number of metal bumps 720.

The processor chip 800 may include, for example, a central processor (CPU), a graphics processor (GPU), a field programmable gate array (FPGA), a digital signal processor (DSP), an encryption processor, a microprocessor, a microcontroller, an analog-to-digital converter, an application-specific integrated circuit (ASIC), or the like.

According to an example embodiment, the semiconductor package 1000C may further include an inner encapsulant covering the chip structure PS and the processor chip 800 on the interposer substrate 700. In addition, the semiconductor package 1000C may further include an outer encapsulant covering the interposer substrate 700 and the inner encapsulant on the package substrate 900. The outer encapsulant and the inner encapsulant may be formed together and may not be distinguished. According to an example embodiment, the semiconductor package 1000C may further include a heat dissipation structure covering the chip structure PS and the processor chip 800.

FIGS. 5A to 5H are cross-sectional views schematically illustrating a manufacturing process of a semiconductor package 1000 according to an example embodiment.

Referring to FIG. 5A, a preliminary base chip 400p for providing a base chip 400 (see FIG. 1B) may be prepared. The preliminary base chip 400p may include elements that constitute the base chip 400. The preliminary base chip 400p may be temporarily attached to the first carrier 10 via the first adhesive film 11 in order to perform subsequent processes. A plurality of preliminary base chips 400p may be attached to the first carrier 10 and the first adhesive film 11, and the plurality of preliminary base chips 400p may be disposed with a sawing line SL therebetween, at a desired (or alternatively, predetermined) interval.

The preliminary base chip 400p may include a semiconductor body 401, a device layer 410, preliminary through-electrodes 430p that penetrate a portion of the semiconductor body 401 and are electrically connected to the device layer 410, and preliminary insulating spacer layers 437p that surround the respective preliminary through-electrodes 430p.

Each of the preliminary through-electrodes 430p may include a via plug 435 filling the inner side of the through-hole and a preliminary barrier layer 431p surrounding the via plug 435. The uppermost part of the preliminary barrier layer 431p may extend to a level higher than the uppermost part of the via plug 435, and the preliminary barrier layer 431p may extend conformally to surround the side and upper surfaces of the via plug 435, but is not limited thereto.

The uppermost part of the preliminary insulating spacer layers 437p may extend to a level higher than the uppermost part of the preliminary barrier layer 431p, and the preliminary insulating spacer layers 437p may extend conformally to surround the side and upper surfaces of the preliminary barrier layer 431p, but the present inventive concepts are not limited thereto.

The uppermost part of the semiconductor body 401 may be located at a level higher than the preliminary insulating spacer layers 437p and the preliminary barrier layer 431p. The preliminary insulating spacer layers 437p and the preliminary barrier layer 431p each may penetrate at least a portion of the semiconductor body 401 and may extend in a vertical direction (e.g., in the Z-axis direction), but the upper surface of the preliminary insulating spacer layers 437p may not be exposed from the semiconductor body 401 and may have a structure surrounded by the semiconductor body 401.

Referring to FIG. 5B, a portion of the semiconductor body 401 of the preliminary base chip 400p is removed to form a semiconductor body 401 having an upper surface 401US located opposite to the lower surface where the device layer 410 is located, and a preliminary buffer insulating layer 530p that conformally covers the semiconductor body 401 and the preliminary insulating spacer layer 437p may be formed.

At least a portion of the upper region of the semiconductor body 401 may be removed through a grinding or Chemical Mechanical Polishing (CMP) process, or the like, to reduce the thickness to a certain extent. Thereafter, a portion of the semiconductor body 401 may be removed by an etching process, so that a base chip 400 with a further reduced thickness may be formed. The semiconductor body 401 may have a thickness such that a plurality of preliminary through-electrodes 430p and a preliminary insulating spacer layer 437p are not exposed to the upper surface 401US. For example, the thickness of the semiconductor body 401 may be smaller than the height of the plurality of preliminary through-electrodes 430p and the preliminary insulating spacer layer 437p. The etching process may be, for example, a reactive-ion etching (RIE) process using a photoresist (not illustrated), and through the etching process, only the semiconductor body 401 excluding the preliminary through-electrodes 430p and the preliminary insulating spacer layer 437p may be selectively removed. The plurality of preliminary through-electrodes 430p may be covered by the preliminary insulating spacer layer 437p. The preliminary insulating spacer layer 437p may include, for example, a High Aspect Ratio Process (HARP) oxide layer. The preliminary buffer insulating layer 530p may include an insulating material such as silicon oxide, and may conformally cover the side and upper surface of the semiconductor body 401, and the preliminary buffer insulating layer 530p may conformally cover the upper surface and side surface of the preliminary insulating spacer layer 437p protruding from the upper surface of the semiconductor body 401.

Referring to FIG. 5C, an insulating material may be filled to cover the semiconductor body 401 of the base chip 400, thereby forming a preliminary insulating pattern 500p.

The preliminary insulating pattern 500p may fill the region 400BR between the plurality of base chips 400, and the preliminary insulating pattern 500p may be formed to a level higher than the upper surface 401US of the semiconductor body 401 so as to cover the side and upper surface of the semiconductor body 401. The preliminary buffer insulating layer 530p may conformally cover the preliminary through-electrodes 430p and the preliminary insulating spacer layers 437p, and the preliminary insulating pattern 500p may cover the preliminary buffer insulating layer 530p. The preliminary insulating pattern 500p may be in direct contact with the preliminary buffer insulating layer 530p, and the preliminary buffer insulating layer 530p may serve as a buffer layer surrounding the base chip 400. The portion of the preliminary insulating pattern 500p that fills the region 400BR between the plurality of base chips 400 and surrounds the side surface 400SS of the base chip 400 may provide the first insulating portion 501 of FIG. 1B, and the portion of the preliminary insulating pattern 500p that surrounds the side surface of the preliminary insulating spacer layers 437p may provide the second insulating portion 502 of FIG. 1B, depending on the subsequent process.

Referring to FIG. 5D, a planarization process may be performed from the upper surface of the preliminary insulating pattern 500p, and the insulating pattern 500 may be formed.

The planarization process may be performed, for example, by a Chemical Mechanical Polishing (CMP) process, and may be performed in a vertical direction (e.g., in the Z-axis direction). As the planarization process is performed, the thickness or height of the preliminary insulating pattern 500p may be reduced, and the thickness may be reduced until at least a portion of the through-electrodes 430 are exposed. According to the planarization process, at least portions of respective upper surfaces of the preliminary insulating spacer layers 437p (see FIG. 4C), the preliminary via plug 435p (see FIG. 4C) and the preliminary barrier layer 431p (see FIG. 4C) may be removed together, and a through-electrode 430 including the via plug 435 and the barrier layer 431, and an insulating spacer layer 437 surrounding the through-electrode 430 may be formed. According to the planarization process, at least a portion of an upper region of the preliminary buffer insulating layer 530p may be removed together, and a buffer insulating layer 530 may be formed. The respective upper surfaces of the through-electrode 430, the insulating spacer layer 437, and the buffer insulating layer 530 may be exposed from the insulating pattern 500, and the upper surface 430US of the through-electrode 430 may be coplanar with the upper surface 500US of the insulating pattern 500.

Referring to FIG. 5E, upper pads 405 may be formed on the respective protrusion portions 430R of the through-electrodes 430.

The upper pads 405 may include at least one metal material among aluminum (Al), copper (Cu), nickel (Ni), tungsten (W), platinum (Pt), and gold (Au), and may be formed through a plating process. The upper pads 405 may be formed on the through-electrodes 430 exposed from the insulating pattern 500, and may be in contact with the upper surfaces of the through-electrodes 430. The upper pads 405 may be in contact with the respective upper surfaces of the via plugs 435 and the barrier layer 431, and may be spaced apart from the semiconductor body 401 of the base chip 400. Between the upper pads 405 and the semiconductor body 401, a second insulating portion 502 of an insulating pattern 500 may be disposed, and the second insulating portion 502 may serve as a protective insulating layer.

Referring to FIG. 5F, a plurality of first semiconductor chips 100 and a second semiconductor chip 200 may be sequentially stacked on a base chip 400 to form a chip stack 100 and 200.

The base chip 400, the plurality of first semiconductor chips 100 and the second semiconductor chip 200 may be electrically connected by connection pads disposed on the upper and lower sides of respective chips and bump structures 150 disposed between the connection pads. A plurality of first semiconductor chips 100 and a second semiconductor chip 200 may be mounted on a base chip 400 by a thermocompression process, and adhesive layers (AL) surrounding the bump structures 150 may be formed by the thermocompression process.

Referring to FIG. 5G, an encapsulant 420 covering the chip stack 100 and 200 may be formed.

The encapsulant 420 may cover the insulating pattern 500. In detail, the encapsulant 420 may cover the upper surface of the first insulating portion 501 and may cover at least a portion of the upper surface of the second insulating portion 502. The encapsulant 420 may be formed by filling of an organic insulating material such as Epoxy Molding Compound (EMC) and then hardening the insulating material, and may be formed to a level higher than the uppermost part of the second semiconductor chip 200 positioned at the top among the chip stack 100 and 200.

Referring to FIG. 5H, the upper surface of the encapsulant 420 may be flattened using a polishing device. The back surface BS2 of the second semiconductor chip 200 may be exposed by the flattening process. The flattening process may be performed, for example, by a Chemical Mechanical Polishing (CMP) process. In addition, after the entire structure formed through the previous process is turned over, the structure may be attached to the second carrier 20 through the second adhesive film 21, and then the lower pads 404 disposed below the device layer 410 of the base chip 400 may be formed.

Referring to FIGS. 1A and 1B, external connection conductors 450 disposed under the base chip 400 may be formed, and the entire structure may be cut along the sawing line SL to form a semiconductor package 1000 of an example embodiment. The external connection conductors 450 may be connected to the lower pads 404.

As set forth above, according to some example embodiments, semiconductor packages having improved reliability may be provided by introducing an insulating pattern disposed at the same level as at least a portion of a base chip.

While some example embodiments have been illustrated and described above, it will be apparent to those skilled in the art that modifications and variations could be made without departing from the scope of the present inventive concepts as defined by the appended claims.

What is claimed is:

1. A semiconductor package comprising:
a base chip including,
a semiconductor body, and
a through-electrode structure penetrating through the semiconductor body, the through-electrode structure having a protrusion portion protruding upwardly of the semiconductor body;
an insulating pattern on a side surface and an upper surface of the base chip;
a chip stack on the base chip and the insulating pattern; and
an encapsulant on the insulating pattern and covering at least a portion of the chip stack,
wherein the insulating pattern includes,
a first insulating portion on a side surface of the semiconductor body, and
a second insulating portion on an upper surface of the semiconductor body, the second insulating portion covering a side surface of the protrusion portion of the through-electrode structure,
the insulating pattern includes an inorganic insulating material, and
the encapsulant includes an organic insulating material.

2. The semiconductor package of claim 1, wherein the insulating pattern has a structure in which the first insulating portion and the second insulating portion are integrally connected.

3. The semiconductor package of claim 1, further comprising:
an upper pad on the through-electrode structure,
wherein the second insulating portion vertically separates the upper pad and the semiconductor body.

4. The semiconductor package of claim 1, wherein
the base chip includes a logic chip, and
the chip stack includes at least one memory chip.

5. The semiconductor package of claim 1, wherein
the insulating pattern includes silicon nitride (SiN), and
the encapsulant includes an Epoxy Molding Compound (EMC).

6. The semiconductor package of claim 1, wherein, when viewed from above, at least a portion of an upper surface of the first insulating portion is at a lower level than an upper surface of the second insulating portion.

7. The semiconductor package of claim 1, wherein the encapsulant includes
a first lower end in a first region, the first region vertically overlapping the semiconductor body, and
a second lower end at a lower level than the first lower end in a second region, the second region not vertically overlapping the semiconductor body.

8. The semiconductor package of claim 1, further comprising:
a lower pad on a lower surface of the base chip; and
a lower protective layer below the lower surface of the base chip and a lower surface of the insulating pattern, the lower protective layer surrounding at least a portion of the lower pad.

9. The semiconductor package of claim 8, wherein the lower protective layer comprises silicon nitride (SiN).

10. The semiconductor package of claim 1, wherein the chip stack includes,
a plurality of first semiconductor chips stacked on the base chip; and
a second semiconductor chip stacked on the plurality of first semiconductor chips,
wherein a thickness of the second semiconductor chip is greater than or equal to a thickness of each of the plurality of first semiconductor chips.

11. The semiconductor package of claim 1, wherein the base chip has a width greater than a width of the chip stack in a direction parallel to the upper surface of the base chip.

12. The semiconductor package of claim 3, further comprising:
a bump structure on the upper pad; and
an adhesive layer surrounding at least a portion of each of the upper pad and the bump structure.

13. A semiconductor package comprising:
a base chip including,
a semiconductor body, and
a through-electrode structure penetrating through the semiconductor body, the through-electrode structure having a protrusion portion protruding upwardly of the semiconductor body;
an insulating pattern on a side surface and an upper surface of the base chip;
a chip stack on the base chip and the insulating pattern; and
an encapsulant on the insulating pattern and surrounding at least a portion of the chip stack,
wherein the through-electrode structure includes,
a via plug,
a barrier layer surrounding a side surface of the via plug, and
an insulating spacer layer surrounding a side surface of the barrier layer, and
the insulating pattern and the encapsulant include different materials from each other.

14. The semiconductor package of claim 13, wherein the insulating pattern covers the upper surface of the semiconductor body and surrounds a side surface of the protrusion portion of the through-electrode structure.

15. The semiconductor package of claim 13, wherein an upper surface of the via plug is coplanar with an upper surface of the insulating pattern.

16. The semiconductor package of claim 15, wherein an upper surface of the insulating spacer layer is coplanar with the upper surface of the insulating pattern.

17. The semiconductor package of claim 13, further comprising:
an upper pad on the through-electrode structure and the insulating pattern,
wherein a lower surface of the upper pad is in contact with an upper surface of the through-electrode structure and an upper surface of the insulating pattern.

18. The semiconductor package of claim 13, further comprising:
a buffer insulating layer between the insulating pattern and the semiconductor body.

19. The semiconductor package of claim 18, wherein the buffer insulating layer includes a first portion extending between a side surface of the protrusion portion of the through-electrode structure and the insulating pattern and a second portion extending between the insulating pattern and the semiconductor body.

20. A semiconductor package comprising:
a base chip;
a chip stack on the base chip, the chip stack including a plurality of first semiconductor chips stacked in a vertical direction;
an insulating pattern including a first insulating portion and a second insulating portion, the first insulating portion being on a side surface of the base chip, the second insulating portion connected to the first portion and extending between the base chip and the chip stack; and
an encapsulant on the insulating pattern, the encapsulant covering at least a portion of a side surface of the chip stack and contacting the insulating pattern, the encapsulant including a material different from a material of the insulating pattern,
wherein the base chip is spaced from the encapsulant by the insulating pattern,
a side surface of the insulating pattern and a side surface of the encapsulant are vertically aligned, and
at least a portion of the first insulating portion has an upper surface at a level lower than an upper surface of the second insulating portion.
